(19) United States
(12) Patent Application Publication
(10) Pub. No.: US 2005/0259833 A1
(43) Pub. Date: Nov. 24, 2005

(54) Frequency responses, apparatus and methods for the harmonic enhancement of audio signals

(76) Inventors: Frank A. Scarpino, Dayton, OH (US); Arturo H. Garcia, Miami, FL (US); Arturo J. Garcia, Miami, FL (US)

Correspondence Address: STEVENS & SHOWALTER LLP, 7019 CORPORATE WAY, DAYTON, OH, 45459-4238, US

(21) Appl. No.: 09/887,606

(22) Filed: Jun. 22, 2001

Related U.S. Application Data
(63) Continuation-in-part of application No. PCT/US00/21912, filed on Aug. 10, 2000.
(63) Continuation-in-part of application No. 09/431,371, filed on Nov. 1, 1999, now abandoned.
(63) Continuation-in-part of application No. 08/989,373, filed on Dec. 12, 1997, now abandoned.
(63) Continuation-in-part of application No. 08/909,807, filed on Aug. 12, 1997, now abandoned.
Application No. 08/909,807 is a continuation-in-part of application No. 08/700,728, filed on Aug. 13, 1996, now Pat. No. 6,275,593.
(63) Continuation-in-part of application No. 08/472,876, filed on Jun. 7, 1995.
Application No. 08/472,876 is a continuation-in-part of application No. 08/021,209, filed on Feb. 23, 1993, now Pat. No. 5,361,306.
(60) Provisional application No. 60/148,787, filed on Aug. 13, 1999.

(51) Int. Cl. H03G 5/00; H03G 3/00

(52) U.S. Cl. 381/98; 381/61

(57) ABSTRACT

A frequency response useful for simply and inexpensively enhancing an audio signal in such a way that the quality of audible sound produced from the enhanced audio signal more closely approaches that of the original sound heard live in an acoustically designed environment.

### RELATED APPLICATIONS

This application is a continuation-in-part to the International Application No. PCT/US00/21912, filed 10 Aug. 2000, entitled DIGITAL FILTER, and was published under PCT Article 21(2) in English on 22 Feb. 2001; is a continuation-in-part of Non-provisional application U.S. Ser. No. 09/431,371, filed Nov. 1, 1999, and entitled DIGITAL FILTER, which claims the priority of Provisional Application U.S. Ser. No. 60/148,787, filed Aug. 13, 1999, and entitled DIGITAL FILTER; is a continuation-in-part of Non-provisional application U.S. Ser. No. 08/989,373, filed Dec. 12, 1997, and entitled APPARATUS AND METHODS FOR ENHANCING ELECTRONIC AUDIO SIGNALS; is a continuation-in-part of Non-provisional application U.S. Ser. No. 08/909,807, filed Aug. 12, 1997, and entitled APPARATUS AND METHODS FOR THE HARMONIC ENHANCEMENT OF ELECTRONIC AUDIO SIGNALS, which is a continuation-in-part of Non-provisional application U.S. Ser. No. 08/700,728, filed Aug. 13, 1996, and entitled APPARATUS AND METHODS FOR THE HARMONIC ENHANCEMENT OF ELECTRONIC AUDIO SIGNALS; is a continuation-in-part of Non-provisional application U.S. Ser. No. 08/472,876, filed Jun. 7, 1995, and entitled APPARATUS AND METHOD OF ENHANCING ELECTRONIC AUDIO SIGNALS, which is a continuation-in-part of U.S. Pat. No. 5,361,306 that issued on 1 Nov. 1994; each of which is owned by the assignee of the present application and incorporated herein by reference in their entirety.

### FIELD OF THE INVENTION

The present invention relates to the use of a frequency response to enhance audio signals so as to improve the quality of sound produced from those signals, particularly, to an apparatus and method for harmonically enhancing an audio signal and, more particularly, to audio systems for lifelike reproduction of sound, e.g., music, voices, naturally occurring or man made sounds, etc.

### BACKGROUND OF THE INVENTION

It is usually considered more pleasurable to hear music, singing or other such complex sounds live, rather than hearing the same sound after it has been converted into an electronic audio signal and re-converted back into audible sound.

Many of the sounds we hear, especially musical notes, are often a composite. For example, a musical note having a basic pitch or fundamental frequency, usually contains components of the fundamental frequency called harmonics. These harmonics create the tonal quality or timbre of the sound, such as a musical note, that is often unique to the musical instrument or other sound producing source. In other words, these harmonics enrich the sound we hear. Numerous sound reproduction systems have been developed in an attempt to add harmonic enhancement to audio signals. However, these systems are often very sophisticated and expensive and the sound quality produced with such systems still falls short of the perceived quality of the original sound heard live.

Therefore, there is a need for a relatively unsophisticated and inexpensive system for producing an enhanced electronic audio signal that, when converted into audible sound, exhibits an improved harmonic quality compared to that of the original input audio signal and has been perceived as more closely duplicating the experience of hearing the original live sound in an acoustically designed environment.

### SUMMARY OF THE INVENTION

A frequency response is provided for simply and inexpensively enhancing audio signals in such a way that the quality of audible sound, produced from the audio signal, more closely approaches that of the sound heard live in an acoustically designed environment. The present invention enhances audio signals (e.g., digital or analog sound) in this way, at least in part, by compensating for two of the most dominant human hearing phenomena that determine the quality of perceived sound.

Human hearing is typically most sensitive (sound appears to be the loudest) at some frequencies (i.e., sensitive frequencies) and less sensitive (sound appears to be quieter) at other frequencies (i.e., insensitive frequencies). This pitch-loudness phenomenon appears to be an “inner” ear effect. In the other human hearing phenomenon, the outer ear tends to mask or suppress tones of lesser intensity when presented together with tones of greater intensity. This suppression phenomenon or masking effect appears to be more pronounced at higher frequencies.

The present invention compensates for the pitch-loudness effect by non uniformly distorting the audio signal so that the resulting audible sound is perceived as being louder at the insensitive frequencies. This enhancing distortion can be accomplished by non-uniformly amplifying the audio signal so as to selectively amplify such insensitive frequencies. This enhancing distortion can also be accomplished by uniformly amplifying the audio signal and then selectively reducing the amplitude of the sensitive frequencies non-uniformly. The present invention can also create an impulse response that “unmasks” the typically masked tones by stretching the tone in the time domain (i.e., increasing the time smear or dwell time) long enough to be heard but not so long as to be “blurred”. The human ear is typically sensitive to sounds as short in duration as about 0.1 milliseconds. Therefore, the present invention typically stretches impulses to at least about 0.1 milliseconds in duration. How much the tone needs to be time smeared to be perceived and how much the tone can be time smeared before becoming perceptively blurred will likely vary from listener to listener.

Put another way, the present invention provides an amplitude shaping function that overcomes both the pitch-loudness phenomenon and the suppression phenomenon, preferably, by providing a linear circuit that possesses two apparently contradictory impulse response characteristics. The impulse response characteristics sought are: (1) a relatively long lasting impulse response and (2) an impulse response with a wide-band characteristic. Conventional thinking teaches that these two characteristics are contradictory in real filters and, hence, unobtainable. High frequency characteristics are revealed by the zero crossings of the impulse response of a linear system. The first zero crossing of the ideal impulse response appears at ½ f_{c} where f_{c} is the cutoff frequency of the linear system. In other words, the zero crossings occur at relatively large time intervals from the impulse and relatively large time intervals from each other. For example, a theoretically ideal low pass filter with a bandwidth from 0 Hz to 20 kHz will have zero crossings in its impulse response at about 50 microseconds. The two zero crossings occur within 100 microseconds, which is 0.1 milliseconds. Furthermore, the sharp cutoff characteristic of such an ideal filter extends the impulse response in time with many oscillations.

The digital devices of the present invention can have an oscillating impulse response. Not intending to be so limited, an exemplary digital device of the present invention, with an oscillatory impulse response, can have zero crossings at approximately 30 and 60 micro-seconds and a total duration of over 150 micro-seconds. Thus, the present invention can offer a broadband digital filter that exhibits the characteristics of both high frequency content and long duration (i.e., time smear or dwell time).

Even the most staccato audio (e.g., musical) passage has a finite duration (theoretically, an impulse signal has zero duration). Therefore, with the present invention, the actual response to even the subtlest sound can be made of a duration significant enough to be effectively heard but will not be stretched so long as to be shrouded and blurred.

Furthermore, the present digital device can be classified in the special class of filters known as minimum-phase filters. The frequency response of a minimum-phase filter may be defined in terms of two components, the magnitude (amplitude) response and the phase response. The magnitude response and phase response of the filter are uniquely related to each other, in that if one is given, the other component can be computed uniquely.

In accordance with a first embodiment of the present invention, a digital filter is provided comprising a series of digitized time coefficients stored in a memory. The time coefficients are mapped to a like number of frequency coefficients. The frequency coefficients are spaced at frequency intervals, have either zero phase angles or linearly spaced phase angles and have amplitudes which are mirrored about a mid frequency to produce periodicity of a time response for the digital filter.

The time coefficients may be even or odd in number. Preferably, they are odd integers greater than or equal to 5, preferably 7, more preferably 9 and most preferably 11. The time coefficients are defined by inverse discrete Fourier transforms of the frequency coefficients.

In one embodiment of the present invention, a portion of the frequency coefficients having frequencies within a free band are selected so as to achieve a generally constant oscillation frequency across a center band which is broader than the free band.

The frequency coefficients are spaced at equal frequency intervals.

In accordance with a second aspect of the present invention, a method of making a digital filter is provided and comprises the step of establishing a plurality of frequency response coefficients separated at frequency intervals. The frequency response coefficients are graphically characterized by a base point, a series of principal points and a series of mirror points and have either zero phase angles or linearly spaced phase angles. The base point has a frequency of zero. A portion of the principal points are situated at frequencies encompassing at least the range of human hearing, or falling within the range of human hearing, and a portion of the mirror points have frequencies and amplitudes which mirror the portion of the principal points when viewed relative to a mid frequency higher than the frequencies of the principal points. The method further comprises the steps of performing inverse discrete Fourier transformations to map the frequency response coefficients into corresponding time response coefficients, and storing the time response coefficients in a digital memory.

Preferably, the portion of the principal points are situated at predetermined frequencies at a minimum within the range of human hearing and have amplitudes that roughly are inversely corresponding to human hearing sensitivity at the predetermined frequencies.

The frequency response coefficients can be established at uniformly spaced frequency intervals or non-uniformly spaced frequency intervals.

The establishing and performing steps preferably comprise the following steps:
selecting a plurality of first frequency response coefficients separated at uniformly spaced frequency intervals, wherein the first frequency response coefficients have either zero phase angles or linearly spaced phase angles and each first frequency response coefficient further has an amplitude and a frequency;
arranging the plurality of first frequency response coefficients in order from lowest frequency to highest frequency to define a list of first frequency response coefficients;
performing inverse discrete Fourier transformations to map the plurality of first frequency response coefficients into corresponding first time response coefficients;
discarding a pair of the first time response coefficients which have equal magnitudes and are positioned adjacent to one another in the list, with remaining time response coefficients defining second time response coefficients;
assessing the effect on a frequency response of the digital filter after discarding the pair of the first time response coefficients;
repeating the performing, discarding and assessing steps until a pair of discarded time response coefficients cause a significant change in the frequency response of the digital filter; and
adding to remaining time response coefficients the pair of discarded time response coefficients causing a significant change in the frequency response of the digital filter. The added and remaining time response coefficients comprise final time response coefficients.

The method of making a digital filter preferably further comprises the steps of: multiplying each of the final time response coefficients by an integer conversion number to define converted final time response coefficients, wherein the conversion number is sufficiently large to permit discarding any remaining fractional portion without losing substantial final time response coefficient accuracy; and discarding from each of the converted final time response coefficients any remaining fractional portion. The conversion number is preferably selected as a power of two.

The assessing step preferably comprises the steps of: generating a first frequency response curve from the first frequency response coefficients; performing discrete Fourier transformations to map the second time response coefficients into corresponding second frequency response coefficients; generating a second frequency response curve from the second frequency response coefficients; and comparing the first and second frequency response curves to determine if the second frequency response curve is substantially different from the first frequency response curve.

Each of the frequency response coefficients has an amplitude and a frequency. The range of human hearing of interest is within a band of frequencies having a low end and a high end. The human hearing range of interest may be the full range (typically from 20 Hz to 20 kHz) or a portion thereof. Many modern audio systems process audio signals of differing bandwidths. For example, (1) analog telephone signals consist of spectra covering about 300 Hz to about 3000 Hz, (2) Voice over Internet Protocol (VoIP) is limited to a range of up to about 8 kHz and (3) streaming audio is subject to other bandwidth restrictions. Preferably, a portion of or all of the frequency response coefficients, having frequencies between a reference or intermediate frequency and the high end, increase in amplitude as per increasing frequencies from the reference frequency toward the high end and up to a significant amplitude peak at a peak high frequency so as to form a high frequency peak on the frequency response curve. It may also be preferable for a portion of or all of the frequency response coefficients, having frequencies between a reference frequency and the low end, to increase in amplitude as per decreasing frequencies from the reference frequency toward the low end and up to a significant amplitude peak at a peak low frequency. Preferably, a portion of or all of the frequency response coefficients, that form the frequency response curve, exhibit both of these frequency response characteristics.

Once a desired frequency response curve is chosen, it can be preferable to lengthen or shorten the width of the desired curve so as to fit within the bandwidth of the particular audio system being used. For example, the desired frequency response curve could have, for example, a bandwidth of from 20 Hz to 20 kHz, with a reference frequency of 3.0 kHz, a peak high frequency of 6.0 kHz and a peak low frequency of 800 Hz. If the bandwidth of the audio system is, for example, 300 Hz to 3 kHz and the same frequency response curve is used, then only that portion of the frequency response curve up to 3 kHz will be used, effectively eliminating the second peak. Instead of doing this, the width of the frequency response curve can be reduced so that all, or at least most, of the curve can fit within the smaller bandwidth of the audio system. This can be accomplished by reducing the reference frequency, peak high frequency and peak low frequency proportionally the same or disproportionately, depending on the resulting enhancement desired.

By a significant amplitude peak it is meant that the amplitude peak is at an amplitude or a frequency or both that is sufficient to result in a harmonic enhancement to the digital sound that is perceptible by the normal human ear, when converted into audible sound. Preferably, the frequency response curve exhibits up to a total of only two or three, significant amplitude peaks between the low end and the high end. However, the frequency response curve of the present invention can include any number of insignificant amplitude peaks. Insignificant amplitude peaks are those that do not add any harmonic enhancement to the digital sound that is perceptible by the normal human ear, when converted into audible sound. Insignificant amplitude peaks can include, for example, peaks that are at frequencies that fall on the edge or outside the range of normal human hearing, and peaks having small amplitudes that do not produce a perceptible change from the enhancement caused by the significant peak or peaks. Such low amplitude insignificant peaks may be in the form of ripples in the frequency response curve (e.g., the portion of the curve that forms a significant amplitude peak). The human ear is typically able to perceive changes in amplitude of about three decibels or more.

In one embodiment of the present invention, the frequency response coefficients, having frequencies between the reference frequency and the high end, increase in amplitude up to a significant amplitude peak at a peak high frequency and decrease in amplitude as per increasing frequencies toward the high end above the peak high frequency. Alternatively or additionally, the frequency response coefficients, having frequencies between the reference frequency and the low end, increase in amplitude up to a significant amplitude peak at a peak low frequency and decrease in amplitude as per decreasing frequencies toward the low end below the peak low frequency.

In another embodiment of the present invention, the frequency response coefficients, having frequencies between the reference frequency and the high end, increase in amplitude up to a significant amplitude peak at a peak high frequency, decrease in amplitude as per increasing frequencies down to a significant amplitude trough at a trough high frequency and increase in amplitude as per increasing frequencies toward the high end.

The reference frequency may fall within a range of from about 501 Hz to about 8018 Hz. The peak high frequency may fall within a range of from about 2004 Hz to about 20045 Hz. The amplification of the frequency response coefficient at the peak high frequency may be from about 1.3 times to about 6.0 times the amplification of the frequency response coefficient at the reference frequency. The peak low frequency may fall within a range of from about 0 Hz to about 2004 Hz. The amplification of the frequency response coefficient at the peak low frequency may be from about 1.1 times to about 3.0 times the amplification of the frequency response coefficient at the reference frequency.

In accordance with a third aspect of the present invention, a method is provided for enhancing a series of digital audio samples comprising: receiving the series of digital audio samples, and generating a driving signal by convolving the series of samples in real time with a series of stored time coefficients. The time coefficients are mapped to a like number of frequency coefficients. The frequency coefficients are spaced at frequency intervals, have either zero phase angles or linearly spaced phase angles, and have amplitudes which are mirrored about a mid frequency.

The method for enhancing a series of digital audio samples may further comprise generating an analog audio signal from the driving signal.

The time coefficients are preferably integer time coefficients.

The step of generating a driving signal can comprise:
repeatedly solving the following equation for Y:
   Y(n)=A₀X(n)+A₁X(n−1)+ . . . +A_{N-1}X(n−[N−1])
where A₀ through A_{N-1} are the stored time coefficients;
X(n) is the most recent sample received;
X(n−1) through X(n−[N−1]) correspond to N−1 samples received prior to sample X(n);
n is the running index of the time coefficients being computed;
N is equal to the number of terms in the equation to the right side of the equal sign; and
wherein calculated values of Y define the driving signal.

The step of generating a driving signal may further comprise dividing the values of Y by a number previously used to convert initial real number time coefficients to integer time coefficients; and discarding any remaining fractional portion of the divided values of Y.

The receiving step may comprise the step of reading the series of digital samples from a digital recording medium or from a compressed file. The receiving step may also comprise the step of downloading audio sample streams from the Internet.

In accordance with a fourth aspect of the present invention, an apparatus is provided for enhancing a series of digital audio samples. The apparatus comprises a device for receiving the series of digital samples and a digital filter comprising a series of stored time response coefficients. The time response coefficients are mapped to a like number of frequency response coefficients. The frequency response coefficients are spaced at frequency intervals, have phase angles of zero and have amplitudes which are mirrored about a mid frequency. The apparatus further comprises a microprocessor for generating a driving signal by convolving the sound samples in real time against the time coefficients.

The receiving device comprises a digital signal reader.

The microprocessor convolves the sound samples in real time against the time response coefficients by repeatedly solving the following equation for Y:
Y(n)=A₀X(n)+A₁X(n−1)+ . . . +A_{N-1}X(n−[N−1])
where A₀ through A_{N-1} are the stored time coefficients;
X(n) is the most recent sample received;
X(n−1) through X(n−[N−1]) correspond to N−1 samples received prior to sample X(n);
n is the running index of the time coefficients being computed;
N is equal to the number of terms in the equation to the right side of the equal sign; and
wherein calculated values of Y define the driving signal.

The microprocessor may further divide the values of Y by a number previously used to convert real number time coefficients to integer time coefficients and discards any remaining fractional portion of the divided values of Y.

The apparatus may further comprise a converting device responsive to the driving signal for generating an analog audio signal from the driving signal.

In accordance with a fifth aspect of the present invention, a filter package is provided having two or more parallel digital filters. A first filter is provided which comprises a series of digitized first time coefficients stored in a first memory. The time coefficients are mapped to a like number of first frequency coefficients. The first frequency coefficients have either zero phase angles or linearly spaced phase angles and have amplitudes which are mirrored about a mid frequency. A second digital filter is provided and comprises a series of digitized second time coefficients at least one of which has a value which is different from each of the first time coefficients. The second time coefficients are stored in a second memory and mapped to a like number of second frequency coefficients. The second frequency coefficients have either zero phase angles or linearly spaced phase angles and have amplitudes which are mirrored about a mid frequency.

Preferably, the number of the first time coefficients is equal to or greater than 5 and the number of the second time coefficients is equal to or greater than 5. The first memory and the second memory may comprise the same memory component.

In accordance with a sixth embodiment of the present invention, an apparatus is provided for enhancing a series of digital audio samples. The apparatus comprises a device for receiving the series of digital samples and a filter package. The filter package has a first digital filter comprising a series of digitized first time response coefficients stored in a first memory. The time coefficients are mapped to a like number of first frequency coefficients. The first frequency coefficients have either zero phase angles or linearly spaced phase angles and have amplitudes which are mirrored about a mid frequency. The filter package also includes a second digital filter comprising a series of digitized second time response coefficients at least one of which has a value which is different from each of the first time coefficients. The second time coefficients are stored in a second memory and mapped to a like number of second frequency coefficients. The second frequency coefficients have either zero phase angles or linearly spaced phase angles and have amplitudes which are mirrored about a mid frequency. The apparatus further includes a microprocessor for generating a driving signal by convolving the sound samples in real time against either the first time response coefficients or the second time response coefficients.

The apparatus may further comprise an input device coupled to the microprocessor for selecting one of the first filter and the second filter. The microprocessor generates the driving signal by convolving the sound samples in real time against the first time response coefficients when the first filter is selected and the second time response coefficients when the second filter is selected. The apparatus may also comprise a converting device responsive to the driving signal for generating an analog audio signal from the driving signal.

In the apparatus of the present invention, the frequency response curve usually does not vary according to the amplitude of the input audio signal. It may be desirable, however, for the apparatus to be structured so that the frequency response curve varies in a desired way along with the amplitude of the input audio signal. For example, the frequency response curve could be made to decrease in amplitude, or increase in amplitude, as the amplitude of the input audio signal increases. The frequency response curve could also be made to increase in amplitude, or decrease in amplitude, as the amplitude of the input audio signal decreases.

### BRIEF DESCRIPTION OF THE DRAWINGS

FIG. 1 is a block diagram of one embodiment of an audio playback system according to the invention.

FIG. 2 is a schematic illustration of a frequency response curve for a digital filter in a first embodiment.

FIG. 3 is a schematic illustration of a frequency response curve for a digital filter in a second embodiment.

FIG. 4 is a schematic illustration of a frequency response curve for a digital filter in a third embodiment.

FIG. 5 is a schematic illustration of a frequency response curve for a digital filter in a fourth embodiment.

FIG. 6 is a schematic illustration of a frequency response curve for a digital filter in a fifth embodiment.

FIG. 7 is a schematic illustration of a frequency response curve for a digital filter in a sixth embodiment.

### DETAILED DESCRIPTION

FIG. 1 illustrates a personal computer 10, organized in accordance with the present invention. In the illustrated arrangement, personal computer 10 has a microprocessor 20, a CD reader 30 and a sound card 40. There also is a digital filter 50 which preferably comprises an array of storage locations 52 within a random access memory. Further portions of the memory (not illustrated) may be devoted to other uses. A series of N time response values, A₀ through A_{N-1}, are tabulated in a written program for downloading into storage locations 52. These response values, hereinafter referred to as time coefficients, are established by a technique described below.

A system clock (not illustrated) causes CD reader 30 to read a series of digitized sound samples, at a predetermined sampling frequency such as 44,100 Hz. Many other sampling rates exist. For example, sampling rates of 22,050 Hz and 11,025 Hz are used in many PC applications. Some audio CD's are now produced using other sampling rates. Digital video disks are produced at sampling rates of 64,000 Hz. The telephone industry samples at a rate of 8000 Hz. The apparatus and methods set out herein are applicable to any sampling rate.

Each sample is designated X(n) at the time of sampling and is stored temporarily in a designated storage location 22. The sound samples are later shifted successively through a series of N−1 other storage locations 22 for generation of time shifted samples X(n−1) through X(n−[N−1]). Storage locations 22, may be thought of as being equivalent to stages of a shift register within microprocessor 20 and are so illustrated in FIG. 1. However, microprocessor 20 may not have sufficient memory for this purpose, and therefore the computer program may cause the sound samples to be shifted through a designated portion of the random access memory.

Microprocessor 20 multiplies each Aₙ by a corresponding X(n), as indicated by the multiplication blocks 24. The AₙX(n) products then are summed as indicated by a set of summation blocks 26. It will be appreciated that microprocessor 20 performs N shift operations, N multiplications and N summations for each sound sample read by CD reader 30. The calculated sums are supplied to sound card 40 at 44,100 Hz and define a driving signal. Operations within CD reader 30 and sound card 40 are effected by conventional calls to the operating system. Shifting of samples, multiplication by time response coefficients and summation is a matter of routine programming and need not be further described.

The control program for personal computer 10 convolves N time response coefficients A₀-A_{N-1} against the entire series of sound samples. Mathematically speaking, the computer repeatedly solves the following equation:
Y(n)=A₀X(n)+A₁X(n−1)+ . . . +A_{N-1}X(n−[N−1])
where A₀ through A_{N-1} are the stored time coefficients;
X(n) is the most recent sample received;
X(n−1) through X(n−[N−1]) correspond to N−1 samples received prior to sample X(n);
n is the running index of the time coefficients being computed;
N is equal to the number of terms in the equation to the right side of the equal sign; and
wherein calculated values of Y define the driving signal.

When sampling at 44,100 Hz, all calculations implied by the above equation must be completed within a sampling interval, Δ, of 22.68 microseconds. Actually much less time is available, because the operating system requires time for performing its normal housekeeping functions and running any other applications which simultaneously may be open. Consequently it is necessary to find a series of discrete values for the time response function which are few in number, yet able to produce the high quality sound reproduction desired. In accordance with a preferred embodiment of this invention it has been found that digital music of the desired quality may be generated for an odd value of N (the number of time response coefficients) as low as 7. A noticeable degree of enhancement of digital music has even been accomplished with a value of N as low as 5. Accordingly, it has been found that the value of N is at least 5, preferably 7, more preferably 9, and most preferably 11. It is also contemplated that the value of N may comprise an odd integer greater than 11. It is further contemplated that the value of N may comprise an even integer greater than or equal to 6, such as 8, 10 or 12. However, it is preferred that N comprise an odd integer.

As described above, the convolution process is carried out in real time using appropriate time response coefficients. These time response coefficients are calculated off-line and are mapped to a like number of frequency coefficients established as discussed below. That procedure generates N frequency coefficients H₀-H_{N-1}, each having a frequency and an amplitude, which are mapped into N time response coefficients A₀-A_{N-1} by use of the discrete inverse Fourier transformation:

$${A}_{n} = \frac{1}{N} {\sum }_{k = 0}^{N - 1} {H}_{k} {ⅇ}^{- ⅈ 2 Π knN}$$

By way of example, N may have a value of 19, which would call for 19 time response coefficients, all derived from a set of 19 frequency coefficients, regularly spaced at intervals Fₛ in accordance with the time-frequency uncertainty principle, a relationship stated in the following equation:

$${F}_{s} = \frac{1}{Δ N}$$

Thus for Δ=1/44,100 and N=19, Fₛ=2321 Hz. The results are set forth in TABLE I below.

TABLE 1

| | Amp of | Amp of | Phase Angle |
|---|---|---|---|
| Freq. ˜Hz | Freq Coeff | Time Coeff | of Time Coeff |
| 0 | 2.5 | 3.0295 | 0 |
| 2321 | 2.5 | 0.4046 | [symbol] |
| 4642 | 2.15 | 0.01 | [symbol] |
| 6963 | 2.4 | 0.1905 | 0 |
| 9284 | 2.6 | 0.0237 | [symbol] |
| 11605 | 2.9 | 0.0694 | [symbol] |
| 13926 | 3.78 | 0.2137 | 0 |
| 16247 | 4.6 | 0.2074 | [symbol] |
| 18568 | 2.6 | 0.1175 | 0 |
| 20889 | 4 | 0.0714 | [symbol] |
| 23210 | 4 | 0.0714 | [symbol] |
| 25531 | 2.6 | 0.1175 | 0 |
| 27852 | 4.6 | 0.2074 | [symbol] |
| 30173 | 3.78 | 0.2137 | 0 |
| 32494 | 2.9 | 0.0694 | [symbol] |
| 34815 | 2.6 | 0.0237 | [symbol] |
| 37136 | 2.4 | 0.1905 | 0 |
| 39457 | 2.15 | 0.01 | [symbol] |
| 41778 | 2.5 | 0.4046 | [symbol] |

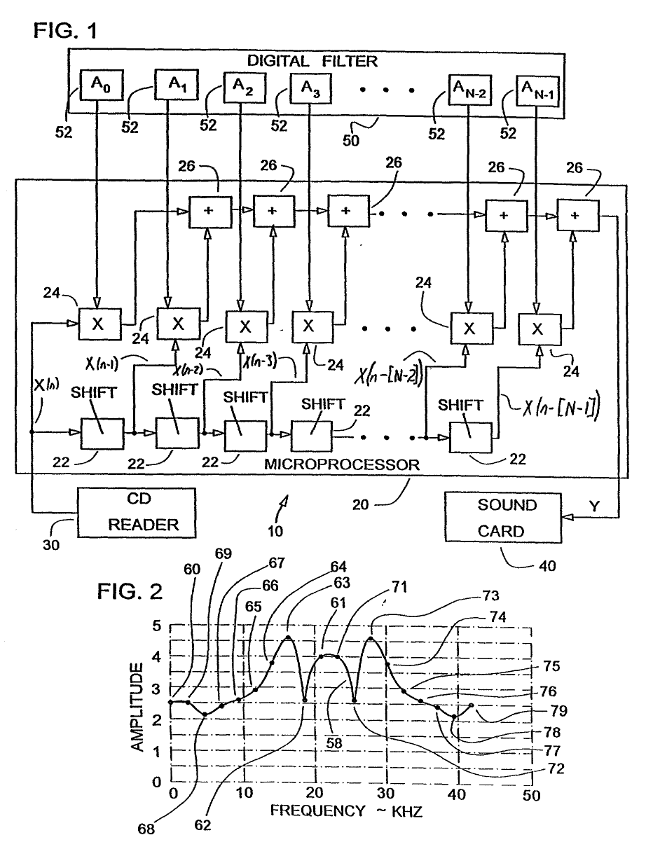

In general the Aₙ and the Hₖ are all complex numbers, having a magnitude and a phase. However, in the practice of a first embodiment of this invention the Hₖ have a phase angle of 0, and the Aₙ have a phase angle of either 0 or [symbol] . Values of [symbol] (i.e., 3.14159) are accommodated in the filter design by assigning a negative value to the amplitude of the time coefficient. The 19 frequency domain points define a frequency response curve 58 extending from 0 to 41,778 Hz as illustrated in FIG. 2. They include a base point 60, principal points 61-69 and mirror points 71-79. The specified numeric amplitudes of the various frequency domain points 60-69 and 71-79 do not have units. The specified amplitudes of these points are all relative to one another. Frequency domain points 60-69 and 71-79 are set at regular intervals of 2321 Hz with mirror points 71-79 having amplitudes equal to principal points 61-69 respectively. It will be observed that the principal points and the mirror points are mirrored about a mid frequency of 22,050 Hz, half the 44,100 Hz sampling frequency. This produces a periodic response at the sampling frequency. That periodicity effectively extends the frequency response curve 58 to 44,100 Hz and sets a virtual point (not illustrated) at 44,100 Hz having a magnitude equal to that of base point 60. This virtual frequency domain point is mapped to a virtual time response point (also not illustrated) equal to, and synchronous with, A₀. Since 19 is an odd number there is no frequency domain point at the mirroring mid frequency.

Since the human ear does not typically respond to frequencies in excess of about 20,000 Hz, the entire information content of the original audio signal can be recorded by low pass filtering at 22,050 Hz, followed by sampling and recording at 44,100 Hz. CDs and other digital recordings are usually prepared in this fashion. That gives two points per cycle of the highest frequency present.

Frequency response points were selected in the range from 20 Hz to 20,000 Hz having amplitudes bearing a roughly inverse relationship to the sensitivity of the human ear over that same range. This flattens out the perceived response of the filter to the regenerated sound. In particular the frequency response was relatively decreased at points 68 and 62 to compensate for regions of increased ear sensitivity near 4642 Hz and 18,568 Hz respectively, and it was relatively increased at point 63 to compensate for reduced ear sensitivity in the region around 16,247 Hz. Thus, as is apparent from FIG. 2, frequency response coefficients 62-69 having frequencies between a reference frequency of 4642 Hz and a high end frequency of 20,000 Hz increase in amplitude as per increasing frequencies from the reference frequency up to a significant amplitude peak at a peak high frequency of 16,247 Hz and decrease in amplitude as per increasing frequencies down to a significant amplitude trough at a trough high frequency of 18,568 Hz. The amplification of the frequency response coefficient at the peak high frequency is about 2.1 times the amplification of the frequency response coefficient at the reference frequency. The frequency response coefficient 69 which is positioned between the reference frequency and a low end frequency of 20 Hz has an amplitude which is slightly greater than that of the frequency response coefficient 68 located at the reference frequency.

The required filter response is undefined outside the range of human hearing. That includes the region below about 20 Hz, a free band region between 20,000 Hz and 24,100 Hz, and an end region between 24,100 Hz and 44,100 Hz. However, the periodic nature of the filtering process requires some definition for all frequencies between zero and the sampling frequency. Therefore, frequency response points or taps were selected at amplitudes which would tend to lend smoothness to the response function in the undefined regions. Hence, point 60 having a frequency of 0 Hz was selected so as to have an amplitude of 2.5, which is equal to the amplitude for point 69, which has a frequency of 2321 Hz. The amplitudes of points 61 and 71, which fall within the free band region, were selected so as to achieve a generally constant oscillation frequency across a center band extending from about 11,605 Hz to about 32,494 Hz, i.e., the portions of the curve defined between points 65,62; 62,72; and 72,75 have approximately the same width. Points 72-79 are mirror images of points 62-69. By selecting the amplitudes of points 60, 61 and 71-79 in the manner discussed above, the number of time coefficients having significant or large magnitudes were reduced. In order to reduce processing time during filtering, the number of time coefficients incorporated into the filter must be minimized. By minimizing the number of time coefficients having significant magnitudes, remaining time coefficients having insignificant magnitudes may be discarded resulting in fewer time coefficients required to achieve a desired frequency response for the filter.

The above described digital filter design procedure was found to produce time response coefficients which, when convolved with typical stored music, rendered output sound of remarkably high quality. It was found that background sound which is ordinarily suppressed during storage, was substantially restored upon playback. Moreover, 19 coefficients did not overwhelm the computer. Having achieved those results, filters having lower values of N were then designed.

The following is a general summary of how a frequency response curve according to the present invention can be affected by manipulating various frequency response points or taps. Also included are some of the characteristics that can occur when manipulating specific taps located in each region of the frequency response curve noted. In general, manipulation of one or more of the taps at frequencies lower than the reference frequency can affect the low frequency response or base region of the frequency response curve (e.g., about 0 Hz to about 2004 Hz). By raising the amplitude of one or more of the taps in the base region, the base of the resulting sound can be made to sound more boomy and thick (i.e., the base sound is over emphasized and it loses some of its detail and clarity). Raising the amplitude of one or more of the base region taps also seems to affect the high frequency response or treble region (above the reference frequency) so that the treble portion sounds thicker and not quite as brilliant (i.e., it loses detail and clarity). That is, affecting the base region in this manner can suppress the treble region in a manner similar to the high frequency masking effect caused by using noise suppression technology like that made by Dolby™. When the amplitude of one or more of the taps in the base region are lowered, the base of the resulting sound can be made to sound much thinner, which can result in the treble region sounding brighter or brittle (i.e., more apparent or over emphasized), depending upon how the taps are adjusted.

In general, manipulation of one or more of the taps within the range of the reference frequency (e.g., about 501 Hz to about 8018 Hz) can affect the reference frequency response of the frequency response curve. Raising the amplitude of one or more of the taps in this region can produce sound appearing to have more air and greater separation between the sound sources, e.g., instruments (i.e., different sound sources are more easily distinguished). This greater separation can make the overall sound appear more like it was live and not recorded. Lowering the amplitude of one or more of the taps in this region can make the resulting signal sound dull and lifeless.

Manipulation of one or more of the taps at frequencies higher than the reference frequency, but within the frequency band “of interest”, can affect the high frequency response or treble region of the frequency response curve (e.g., about 2004 Hz to about 20045 Hz). By raising the amplitude of the taps in the treble region, more brilliance can be added to the resulting sound. In this way, a greater amount of detail can be offered, especially in audio application like, for example, a movie soundtrack. By lowering the amplitude of the taps in the treble region, the resulting sound can be made to sound flat and muted or muddy.

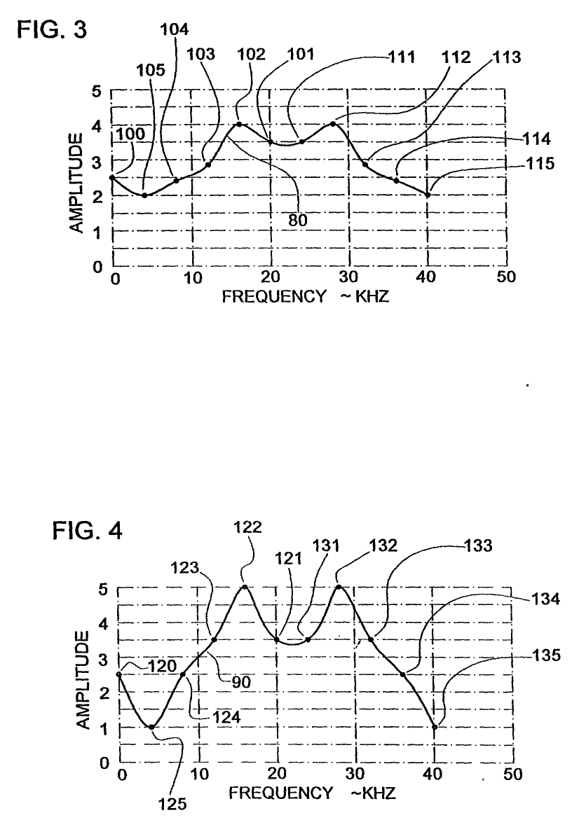

Manipulation of one or more of the taps out beyond the frequency band “of interest” (i.e., the center region where the curve is folded upon itself) can affect the dwell time of the signal, especially when the frequencies of the taps are at the edge or above the band of normal human hearing (e.g., about 20 Hz to about 20,000 Hz). For example, the center region of the frequency response curve of FIG. 3 contains taps 101 and 111. By raising the amplitude of the taps in this region, the dwell time can be reduced and the resulting enhancement can sound more like a mere amplitude shift, rather than overall harmonic enhancement. Increasing the amplitude of these taps can also increase the rate of clipping or overdriving of a signal. In addition, by lowering the amplitude of the taps in this region, the dwell time can be increased and the overall enhancement and stability of the audio signal improved, with a reduction in the risk of the signal being clipped. The dwell time can be dramatically affected by changes in the amplitude of the center region taps, regardless of the number of the center region taps. The rate of transition between the frequency band of interest and the center region can be controlled by adjusting the amplitude of one or more of the center region taps.

Surprisingly, it has been found that the cutoff characteristic between the frequency band of interest and the center region (i.e., the sharpness with which the band edge is formed) can be used to control the dwell time and, consequently, the enhancement imparted to the digital audio signal. As the dwell time increases, certain frequencies exhibit an increase in loudness (as sounds are stretched in time they appear to be louder). This increase in “dwell time” is responsible for unmasking previously masked tones and leads to a preferred enhancement. Dwell time is defined here as the time interval over which the impulse response of the filter has significant amplitude. For a filter with a fixed number of taps (i.e., a finite impulse response filter), the actual time duration of the impulse response cannot be modified.

A digital filter in accordance with a second embodiment of the present invention was created as follows. A set of first frequency response coefficients separated at uniformly spaced frequency intervals were selected. The first frequency response coefficients had zero phase angles. In the illustrated embodiment, the frequency response coefficients set out in Table 1 above were used as the first frequency response coefficients. By the use of discrete inverse Fourier transformation, the plurality of first frequency response coefficients were mapped into corresponding first time response coefficients, which are also set out in Table 1.

As noted above, in order to reduce processing time during filtering, the number of time coefficients should be minimized. So as to achieve that end, a pair of the first time response coefficients having equal magnitudes and being positioned adjacent to one another in Table 1 were removed. The discarded pair of time coefficients each had a magnitude of 0.0714. The remaining time coefficients defined second time coefficients.

If an even number of first time response coefficients are provided, the one first time response coefficient not having a zero frequency and not having a mate of equal magnitude is also discarded.

The effect of removing the pair of time coefficients on the frequency response of the digital filter was then assessed. This involved generating a first frequency response curve from the first frequency response coefficients. The second time response coefficients were mapped into corresponding second frequency response coefficients by use of the discrete Fourier transformation:

$${H}_{k} = {\sum }_{n = 0}^{N - 1} {A}_{n} {ⅇ}^{- ⅈ \frac{2 Π kn}{N}}$$

A second frequency response curve was then generated using the second frequency response coefficients. The first and second frequency response curves were compared to determine if the second frequency response curve was substantially different from the first frequency response curve. If not, then another pair of time response coefficients, i.e., a pair of the second time response coefficients, having equal magnitudes and being positioned adjacent to one another were removed. This process of removing and assessing continued until a pair of discarded time response coefficients caused a significant change in the perceived enhancement caused by the frequency response of the digital filter. A significant change in the perceived enhancement caused by the frequency response of the digital filter corresponds to a substantial difference between an initial and a subsequent frequency response curve. When a significant change occurred, this last pair of discarded time response coefficients were added back to the time response coefficients. These remaining time response coefficients defined final time response coefficients.

In order to reduce processing time, it is preferred that the time response coefficients comprise integer numbers. In order to convert the final time response coefficients into integers, they were multiplied by an integer conversion number sufficiently large to permit any remaining fractional portion to be discarded without losing substantial final time response coefficient accuracy. A substantial loss in final time response coefficient accuracy occurs when the resulting frequency response of the digital filter produces an enhancement perceptibly different from the desired enhancement. It is also preferred that the integer conversion number be selected as a power of two so that shifting may be used in place of division when subsequent renormalization occurs for calculated values of Y. In the illustrated embodiment, the final time coefficients (set out in brackets in Table 2 below) were multiplied by 2¹³ (8192). Any remaining fractional portions of the converted time coefficients were discarded. The integer final time coefficients are set out in Table 2 below. They may be tabulated in a written program for downloading into storage locations 52. This filter has 11 time response coefficients.

Prior to the microprocessor 20 supplying the calculated values of Y to the sound card 40, the microprocessor 20 must renormalize those values. This involves dividing each value of Y by the integer conversion number. Alternatively, if the integer conversion number is selected as a power of two, the microprocessor 20 can effect renormalization by right shifting an appropriate number of bit positions, 13 in the illustrated embodiment.

A frequency response curve 80 plotted from the final frequency response coefficients, set out in Table 2, is shown in FIG. 3. Curve 80 has a base point 100. It also has principal points 101-105, which are mirrored by points 111-115. As is apparent from FIG. 3, frequency response coefficients 102-105 having frequencies between a reference frequency of 4009 Hz and a high end frequency of 20,000 Hz increase in amplitude as per increasing frequencies from the reference frequency toward the high end.

TABLE 2

| | Amp of | | | Phase of |
|---|---|---|---|---|
| Freq. ˜Hz | Freq Coeff | Amp of Time Coeff | | Time Coeff |
| 00000 | 2.50 | 23,980 | (2.9273) | 0 |
| 04009 | 2.00 | 3,593 | (.4386) | [symbol] |
| 08018 | 2.40 | 125 | (0.0153) | 0 |
| 12027 | 2.85 | 1226 | (0.1497) | 0 |
| 16036 | 4.00 | 598 | (0.0731) | [symbol] |
| 20045 | 3.50 | 1089 | (0.1330) | 0 |
| 24054 | 3.50 | 1089 | (0.1330) | 0 |
| 28063 | 4.00 | 598 | (0.0731) | [symbol] |
| 32072 | 2.85 | 1226 | (0.1497) | 0 |
| 36081 | 2.40 | 125 | (0.0153) | 0 |
| 40090 | 2.00 | 3,593 | (0.4386) | [symbol] |

A filter in accordance with a third embodiment of the present invention was created using the same design procedures undertaken to construct the filter of the second embodiment. The third filter's final frequency and time response coefficients are set out in Table 3 below. The final time response coefficients both before and after being multiplied by an integer conversion number equal to 8192 are set out in Table 3. A frequency response curve 90 plotted using the final frequency response coefficients is shown in FIG. 4. The curve has a base point 120, principal points 121-125 and mirror points 131-135. As is apparent from FIG. 4, frequency response coefficients 122-125 having frequencies between a reference frequency of 4009 Hz and a high end frequency of 20,000 Hz increase in amplitude as per increasing frequencies from the reference frequency toward the high end.

TABLE 3

| | Amp of | | | Phase of |
|---|---|---|---|---|
| Freq. ˜Hz | Freq Coeff | Amp of Time Coeff | | Time Coeff |
| 00000 | 2.50 | 24,948 | (3.0455) | 0 |
| 04009 | 1.00 | 5958 | (0.7274) | [symbol] |
| 08018 | 2.50 | 1634 | (0.1995) | [symbol] |
| 12027 | 3.50 | 3094 | (0.3777) | 0 |
| 16036 | 5.00 | 237 | (0.0290) | [symbol] |
| 20045 | 3.50 | 2503 | (0.3056) | 0 |
| 24054 | 3.50 | 2503 | (0.3056) | 0 |
| 28063 | 5.00 | 237 | (0.0290) | [symbol] |
| 32072 | 3.50 | 3094 | (0.3777) | 0 |
| 36081 | 2.50 | 1634 | (0.1995) | [symbol] |
| 40090 | 1.00 | 5958 | (0.7274) | [symbol] |

The above description of the invention teaches a straight forward calculation of the sound card driving signal, Y. A more preferred procedure takes advantage of an observed symmetry in the time coefficients. That is, Aₘ=Aₙ where 0<n≦(N+1)/2 and m=N−n. In the case where N=11 a simplified calculation of the sound card driving signal takes the from:
Y=A₀X₀+A₁(X₁+X₁₀)+A₂(X₂+X₉)+A₃(X₃+X₈)+A₄(X₄+X₇)+A₅(X₅+X₆)

This reduces the number of time consuming multiplications. The procedure may be extended to other values of N.

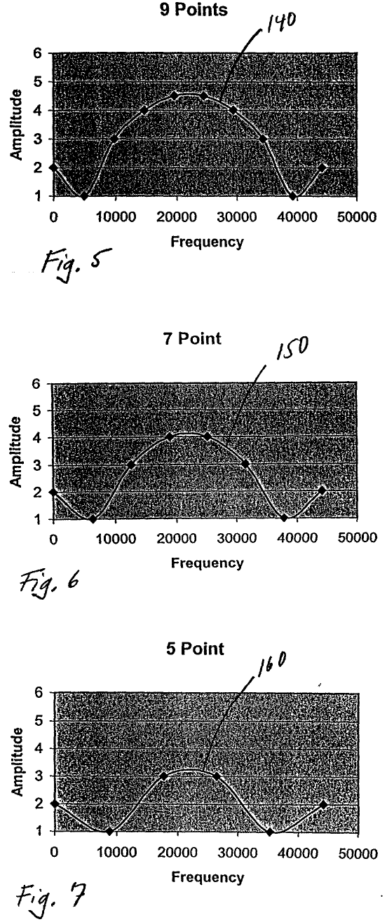

Final frequency and time response coefficients for filters of fourth, fifth and sixth embodiments of the present invention are set out in Tables 4-6 below. The final time response coefficients both before and after being multiplied by an integer conversion number equal to 8192 are set out in Tables 4-6. Nine frequency and time response coefficients are provided for the filter set out in Table 4; seven frequency and time response coefficients are provided for the filter set out in Table 5; and five frequency and time response coefficients are provided for the filter set out in Table 6. A frequency response curve 140 for the fourth filter is shown in FIG. 5, a frequency response curve 150 for the fifth filter is shown in FIG. 6, and a frequency response curve 160 for the six filter is shown in FIG. 7. The fourth and fifth filters provided an enhancement which is comparable to that provided by the first, second and third filters set out in Tables 1-3. While the enhancement of the sixth filter was not equal to that of the fourth and fifth filters, a noticeable enhancement did occur.

TABLE 4

| | Amp of | | | Phase of |
|---|---|---|---|---|
| Freq. ˜Hz | Freq Coeff | Amp of Time Coeff | | Time Coeff |
| 0 | 2 | 24,576 | (3.0000) | 0 |
| 4900 | 1 | 7175 | (0.8759) | Π |
| 9800 | 3 | 361 | (0.0441) | Π |
| 14700 | 4 | 1365 | (0.1667) | 0 |
| 19600 | 4.5 | 2075 | (0.2533) | 0 |
| 24500 | 4.5 | 2075 | (0.2533) | 0 |
| 29400 | 4 | 1365 | (0.1667) | 0 |
| 34300 | 3 | 361 | (0.0441) | Π |
| 39200 | 1 | 7175 | (0.8759) | Π |

TABLE 5

| | Amp of | | | Phase of |
|---|---|---|---|---|
| Freq. ˜Hz | Freq Coeff | Amp of Time Coeff | | Time Coeff |
| 0 | 2 | 21,064 | (2.5714) | 0 |
| 6300 | 1 | 6198 | (0.7566) | Π |
| 12600 | 3 | 1330 | (0.1624) | 0 |
| 18900 | 4 | 2526 | (0.3084) | 0 |
| 25200 | 4 | 2526 | (0.3084) | 0 |
| 31500 | 3 | 1330 | (0.1624) | 0 |
| 37800 | 1 | 6198 | (0.7566) | Π |

TABLE 6

| | Amp of | | | Phase of |
|---|---|---|---|---|
| Freq. ˜Hz | Freq Coeff | Amp of Time Coeff | | Time Coeff |
| 0 | 2 | 16,384 | (2.000) | 0 |
| 8820 | 1 | 3663 | (0.4472) | Π |
| 17640 | 3 | 3663 | (0.4472) | 0 |
| 26460 | 3 | 3663 | (0.4472) | 0 |
| 35280 | 1 | 3663 | (0.4472) | Π |

Filters constructed in accordance with the present invention may have a reference frequency which falls within the range of from about 501 Hz to about 8018 Hz; a peak high frequency which falls within the range of from about 1002 Hz to about 20045 Hz; a trough high frequency which can fall at any frequency after the peak high frequency; and a peak low frequency which falls within the range of from about 0 Hz to about 2004 Hz. It is further contemplated that the amplification of the frequency response coefficient at the peak high frequency may be about 1.3 times to about 6.0 times the amplification of the frequency response coefficient at the reference frequency. It is also contemplated that the amplification of the frequency response coefficient at the peak low frequency may be about 1.1 times to about 3.0 times the amplification of the frequency response coefficient at the reference frequency.

It is also contemplated that filters of the present invention, including the filters set out herein may be used with a microprocessor or like device coupled to a digital signal reader (e.g., a real audio editor, CD or DVD player, etc.) which reads digital signals. The source of such digital signals can be digital samples stored on a digital recording medium as well as digital signals from, for example, audio streams (i.e., compressed packets of digital information) received, for example, over the Internet; MP3, liquid audio, a2b, and other compressed files received over the Internet and stored on any conventional memory device; etc. When uncompressed data is read, the audio signals may be processed directly. When compressed data is read, the data must be uncompressed prior to processing. Instead of sending the driving signal directly to a sound card, it is contemplated that a microprocessor, after generating the driving signal or Y-values, may store the driving signal in any conventional memory device capable of storing digital data, transfer the driving signal over the Internet, the airways (via for example radio or television signals, microwaves, etc.), a network, cable TV lines, the telephone lines, etc. to another digital signal reader, or digital signal storing device.

While the filtering according to the present invention can be performed on a digital signal before it is compressed or after it is uncompressed, it has been found preferable for digital audio signals to be filtered according to the present invention before being compressed. When comparing a recorded compressed audio format that was enhanced by the present filtering technique prior to the compression process, to one enhanced after compression, a significant difference in overall sound quality has resulted. Whether an audio format has been enhanced according to the preset invention before or after compression, the enhanced file always sounds better than the same recording without the present enhancement.

Audio signal compression works by applying a mathematical transform (e.g., Discrete Cosine Transform or DCT) to the audio signal, resulting in a set of DCT frequency coefficients (i.e., “coefficients”). These coefficients are used to recreate the original audio file, as needed. In an attempt to compress the information in the original audio file, the compression process typically includes a quantizing step in which the subtlest characteristics of the digital audio file (often high frequency coefficients) are discarded, since they usually turn out to be small and are believed not necessary to substantially recreate the original audio file. This discarding of coefficients means that the audio file will not be able to be completely reconstructed from the remaining coefficients. Thus, when the file is recreated, it is not the same as the original file. If all of the original coefficients were retained, then the reconstruction would be the same as the original. For this reason, audio signal compression techniques (e.g., MP3) are often referred to as “Lossy” transformations.

When the original digital audio file is enhanced (filtered) according to the present invention, the frequency characteristics of the original file are altered so as to emphasize the characteristics of the sound to which the ear is less sensitive. By emphasizing these more subtle portions of the original sound, the corresponding coefficients of the audio file are less likely to be evaluated by the DCT as being small and, therefore, subject to quantizing. If the coefficients are not considered small, they are less likely to be discarded. It is the most dominant signal characteristics (i.e., typically those located around the reference frequency) that are the more likely to be discarded. Put another way, the present invention enhances the portions of the signals that would normally have been suppressed by the compression process. But, because they are now enhanced, the compression scheme no longer considers them to be naturally masked tones (either by temporal or frequency positioning) by virtue of their new relative amplitudes. The compression methods then retain these subtle sounds. The result is a more enhanced sound after decompression (i.e., the resulting audio signal sounds more like or better than the pre-compressed sound).

Frequency response coefficients for a filter of a seventh embodiment of the present invention are set out in Table 6A below. The frequency response coefficients have linearly spaced phase angles. This is in contrast to the zero phase angles of the time response coefficients set out in Tables 1-6 above. The frequency response coefficient may be mapped into corresponding time response coefficients by use of the discrete inverse Fourier transformation set out above.

TABLE 6A

| Freq. ˜Hz | Amp of Freq. Coeff | Phase Angle of Freq. Coeff |
|---|---|---|
| 0 | 2.5 | 0 |
| 4009 | 1 | −0.57 |
| 8018 | 2.5 | −1.14 |
| 12027 | 3.5 | −1.71 |
| 16036 | 5 | −2.28 |
| 20045 | 3.5 | −2.85 |
| 24054 | 3.5 | −3.42 |
| 28063 | 5 | −3.99 |
| 32072 | 3.5 | −4.56 |
| 36081 | 2.5 | −5.13 |
| 40090 | 1 | −5.7 |
| 44099 | 2.5 | −6.27 |

It is additionally contemplated that two or more of the filters described herein may be stored in a memory component as a filter package such that a user can select any one of the filters making up the package for use in enhancing digital audio samples. For example, a filter package may comprise a first filter having a series of digitized first time coefficients stored in the memory component. The first time coefficients are mapped to a like number of first frequency coefficients. The first frequency coefficients have either zero phase angles or linearly spaced phase angles and have amplitudes which are mirrored about a mid frequency. The filter package further includes a second digital filter comprising a series of digitized second time coefficients at least one of which has a value which is different from each of the first time coefficients. The second time coefficients are stored in a second memory and mapped to a like number of second frequency coefficients. The second frequency coefficients have either zero phase angles or linearly spaced phase angles and have amplitudes which are mirrored about a mid frequency.

An input device (not shown) such as a keyboard is coupled to a microprocessor for allowing the user to select one of the first and second filters for use at any given time for enhancement of digital audio samples. The microprocessor generates a driving signal by convolving the sound samples in real time against the first time response coefficients when the first filter is selected and the second time response coefficients when the second filter is selected. The apparatus may also comprise a converting device responsive to the driving signal for generating an analog audio signal from the driving signal.

It is contemplated that the filter package may be provided to a prospective customer who intends to purchase a hardware version of a digital filter. Each filter of the software filter package is then tested by the customer. Once a desired filter is selected, the filter manufacturer designs a hardware version of the selected filter and provides it to the customer for testing. Accordingly, the digital filter package allows a filter manufacturer to provide two or more filters to a prospective customer for testing without having to design and build two or more separate hardware filters.

It is contemplated that the time coefficients set out in Table 1 may be multiplied by an integer conversion number.

The digital filters disclosed above are finite impulse response (FIR) filters. The procedure for designing an infinite impulse response (IIR) filter implementation can be very similar to the above described FIR procedure. Assuming that a desired frequency response has been specified at various frequencies, an IIR filter can be developed using the same technique described above for the FIR filter implementation.

Using a conventional IIR filter coefficient computation technique, such as that found in Matlab (a software system for filter design and digital signal processing), choose an IIR filter order and input the desired filter order and frequency response. The Matlab function will return the IIR filter coefficients that meet the frequency response and filter order requirements, within some tolerance that is a function of the chosen filter order. Note that the IIR filter has the form (first-order example), as follows:
y(k)=b0*x(k)+a1*y(k−1)
so that there are feedback terms involving the output. The FIR includes terms from the input, i.e., x(k).

The filter coefficients are prepared for real-time implementation as in the FIR case. Each coefficient is multiplied by a large number and the decimal portion of the result is eliminated. In this way the coefficients are made integers, which can make the real-time implementation faster for most computer systems. Because improper scaling could lead to instability, care should be taken when performing this operation with an IIR filter due to the feedback term.

The IIR filter has the advantage of potentially requiring fewer coefficients and therefore a more efficient real-time implementation. This means that an IIR filter may take less time to compute an output sample than an equivalent FIR filter. A possible disadvantage of the IIR filter is that it typically does not possess linear phase. If the filter design requires a linear phase, as is preferred for the frequency response described above, then an FIR filter is normally the only choice. The IIR filter may have approximately linear phase and may only approximate the magnitude response, depending on the order of the IIR filter specified in the design. It is possible to obtain linear phase from an IIR filter by running the data through the IIR filter twice (both forward and backward). However, this doubles the order of the filter.

The follow equation is a 3rd order IIR filter approximation of the frequency response disclosed above.
y(k)=0.0355x(k)−0.0709x(k−1)+0.1509x(k−2)+0.0533x(k−3)−0.2944y(k−1)−0.0399y(k−2)+0.1033y(k−3)

Upon comparison, there will likely be some difference between the original FIR frequency response and the 3rd order IIR filter frequency response. Although they are similar in amplitude and shape, they may create slightly noticeable differences in music quality. In addition, the phase response for the 3rd order IIR filter is nonlinear, especially at the higher frequencies, although it appears to be very linear up to about 15 kHz. Hence, at higher frequencies the nonlinear phase may also contribute to noticeable differences in reproduction quality.

Final frequency and time response coefficients for other FIR digital filters of the present invention are set out below in Tables 7- 34. The final time response coefficients have not yet been multiplied by an integer conversion factor.

TABLE 7

| Freq | Amplitude | Time Coefficient | Phase |
|---|---|---|---|
| 0 | 2 | 2.7273 | 0 |
| 4009 | 1 | 0.6916 | 3.1416 |
| 8018 | 2 | 0.1595 | 3.1416 |
| 12027 | 3.5 | 0.2665 | 0 |
| 16036 | 4 | 0.1129 | 0 |
| 20045 | 3.5 | 0.1081 | 0 |
| 24054 | 3.5 | 0.1081 | 0 |
| 28063 | 4 | 0.1129 | 0 |
| 32072 | 3.5 | 0.2665 | 0 |
| 36081 | 2 | 0.1595 | 3.1416 |
| 40090 | 1 | 0.6916 | 3.1416 |

Phase means phase of the time coefficient. All Frequency phases are zero.

TABLE 8

| Freq | Amplitude | Time Coefficient | Phase |
|---|---|---|---|
| 0 | 1.72 | 1.8709 | 0 |
| 4009 | 1 | 0.4524 | 3.1416 |
| 8018 | 1.35 | 0.2061 | 0 |
| 12027 | 1.65 | 0.0067 | 3.1416 |
| 16036 | 2.28 | 0.0949 | 0 |
| 20045 | 3.15 | 0.0826 | 0 |
| 24054 | 3.15 | 0.0826 | 0 |
| 28063 | 2.28 | 0.0949 | 0 |
| 32072 | 1.65 | 0.0067 | 3.1416 |
| 36081 | 1.35 | 0.2061 | 0 |
| 40090 | 1 | 0.4524 | 3.1416 |

Phase means phase of the time coefficient. All Frequency phases are zero.

TABLE 9

| Freq | Amplitude | Time Coeff | Phase |
|---|---|---|---|
| 0 | 2.5 | 3.1091 | 0 |
| 4009 | 2 | 0.5577 | 3.1416 |
| 8018 | 2.5 | 0.0106 | 3.1416 |
| 12027 | 2.85 | 0.3027 | 0 |
| 16036 | 5 | 0.2475 | 3.1416 |
| 20045 | 3.5 | 0.2085 | 0 |
| 24054 | 3.5 | 0.2085 | 0 |
| 28063 | 5 | 0.2475 | 3.1416 |
| 32072 | 2.85 | 0.3027 | 0 |
| 36081 | 2.5 | 0.0106 | 3.1416 |
| 40090 | 2 | 0.5577 | 3.1416 |

Phase means phase of the time coefficient. All Frequency phases are zero.

TABLE 10

| Freq | Amplitude | Time Coefficient | Phase |
|---|---|---|---|
| 0 | 2.5 | 2.9273 | 0 |
| 4009 | 1 | 0.7106 | 3.1416 |
| 8018 | 2.5 | 0.0861 | 3.1416 |
| 12027 | 2.85 | 0.3286 | 0 |
| 16036 | 5 | 0.1285 | 3.1416 |
| 20045 | 3.5 | 0.383 | 0 |
| 24054 | 3.5 | 0.383 | 0 |
| 28063 | 5 | 0.1285 | 3.1416 |
| 32072 | 2.85 | 0.3286 | 0 |
| 36081 | 2.5 | 0.0861 | 3.1416 |
| 40090 | 1 | 0.7106 | 3.1416 |

Phase means phase of the time coefficient.
All Frequency phases are zero.

TABLE 11

| Freq | Amplitude |
|---|---|
| 0 | 2.1 |
| 2321 | 2 |
| 4642 | 1 |
| 6963 | 1 |
| 9284 | 1 |
| 11605 | 1 |
| 13926 | 1 |
| 16247 | 1 |
| 18568 | 1 |
| 20889 | 1 |
| 23210 | 1 |
| 25531 | 1 |
| 27852 | 1 |
| 30173 | 1 |
| 32494 | 1 |
| 34815 | 1 |
| 37136 | 1 |
| 39457 | 1 |
| 41778 | 2 |

TABLE 12

| Freq | Amplitude |
|---|---|
| 0 | 1.6 |
| 21050 | 1.5 |
| 42100 | 1 |
| 63150 | 1.12 |
| 84200 | 1.2 |
| 105250 | 1.3 |
| 126300 | 1.4 |
| 147350 | 1.6 |
| 168400 | 2 |
| 189450 | 1.9 |
| 210500 | 1.9 |
| 231550 | 2 |
| 252600 | 1.6 |
| 273650 | 1.4 |
| 294700 | 1.3 |
| 315750 | 1.2 |
| 336800 | 1.12 |
| 357850 | 1 |
| 378900 | 1.5 |

TABLE 13

| Freq | Amplitude |
|---|---|
| 0 | 1.51 |
| 1764 | 1.72 |
| 3528 | 1 |
| 5292 | 1.15 |
| 7056 | 1.21 |
| 8820 | 1.36 |
| 10584 | 1.41 |
| 12348 | 1.65 |
| 14112 | 1.98 |
| 15876 | 2.12 |
| 17640 | 2.49 |
| 19404 | 2.31 |
| 21168 | 2.11 |
| 22932 | 2.11 |
| 24696 | 2.31 |
| 26460 | 2.49 |
| 28224 | 2.12 |
| 29988 | 1.98 |
| 31752 | 1.65 |
| 33516 | 1.41 |
| 35280 | 1.36 |
| 37044 | 1.21 |
| 38808 | 1.15 |
| 40572 | 1 |
| 42336 | 1.72 |
| 44100 | 1.51 |

TABLE 14

| Freq | Amplitude |
|---|---|
| 0 | 1.61 |
| 3392 | 1 |
| 6784 | 1.19 |
| 10176 | 1.41 |
| 13568 | 1.72 |
| 16960 | 2.49 |
| 20352 | 2.27 |
| 23744 | 2.27 |
| 27136 | 2.49 |
| 30528 | 1.72 |
| 33920 | 1.41 |
| 37312 | 1.19 |
| 40704 | 1 |

TABLE 15

| Freq | Amplitude |
|---|---|
| 0 | 1.7 |
| 2310 | 1.6 |
| 4620 | 1 |
| 6930 | 1.2 |
| 9240 | 1.3 |
| 11550 | 1.4 |
| 13860 | 1.5 |
| 16170 | 1.6 |
| 18480 | 2.1 |
| 20790 | 2 |
| 23100 | 2 |
| 25410 | 2.1 |
| 27720 | 1.6 |
| 30030 | 1.5 |
| 32340 | 1.4 |
| 34650 | 1.3 |
| 36960 | 1.2 |
| 39270 | 1 |
| 41580 | 1.6 |

TABLE 16

| Freq | Amplitude |
|---|---|
| 0 | 1.72 |
| 4009 | 1 |
| 8018 | 1.35 |
| 12027 | 1.8 |
| 16036 | 3 |
| 20045 | 3.15 |
| 24054 | 3.15 |
| 28063 | 3 |
| 32072 | 1.8 |
| 36081 | 1.35 |
| 40090 | 1 |

TABLE 17

| Freq | Amplitude |
|---|---|
| 0 | 1.72 |
| 4009 | 1 |
| 8018 | 1.35 |
| 12027 | 2 |
| 16036 | 3.5 |
| 20045 | 3.15 |
| 24054 | 3.15 |
| 28063 | 3.5 |
| 32072 | 2 |
| 36081 | 1.35 |
| 40090 | 1 |

TABLE 18

| Freq | Amplitude |
|---|---|
| 0 | 2 |
| 4009 | 1 |
| 8018 | 1.35 |
| 12027 | 2 |
| 16036 | 4 |
| 20045 | 3.15 |
| 24054 | 3.15 |
| 28063 | 4 |
| 32072 | 2 |
| 36081 | 1.35 |
| 40090 | 1 |

TABLE 19

| Freq | Amplitude |
|---|---|
| 0 | 2 |
| 4009 | 1 |
| 8018 | 1.35 |
| 12027 | 1.65 |
| 16036 | 2.59 |
| 20045 | 3.5 |
| 24054 | 3.5 |
| 28063 | 2.59 |
| 32072 | 1.65 |
| 36081 | 1.35 |
| 40090 | 1 |

TABLE 20

| Freq | Amplitude | Time Coefficient | Phase |
|---|---|---|---|
| 0 | 2.5 | 2.8684 | 0 |
| 2321 | 2.5 | 0.3105 | 3.1416 |
| 4642 | 2 | 0.0385 | 3.1416 |
| 6963 | 2.3 | 0.1654 | 0 |
| 9284 | 2.5 | 0.0134 | 0 |
| 11605 | 2.9 | 0.0268 | 3.1416 |
| 13926 | 3.5 | 0.1568 | 0 |
| 16247 | 4 | 0.1367 | 3.1416 |
| 18568 | 2.6 | 0.0653 | 0 |
| 20889 | 3.5 | 0.0727 | 3.1416 |
| 23210 | 3.5 | 0.0727 | 3.1416 |
| 25531 | 2.6 | 0.0653 | 0 |
| 27852 | 4 | 0.1367 | 3.1416 |
| 30173 | 3.5 | 0.1568 | 0 |
| 32494 | 2.9 | 0.0268 | 3.1416 |
| 34815 | 2.5 | 0.0134 | 0 |
| 37136 | 2.3 | 0.1654 | 0 |
| 39457 | 2 | 0.0385 | 3.1416 |
| 41778 | 2.5 | 0.3105 | 3.1416 |

Phase means phase of the time coefficient.
All Frequency phases are zero.

TABLE 21

| Freq | Amplitude |
|---|---|
| 0 | 2.5 |
| 4009 | 1 |
| 8018 | 2.5 |
| 12027 | 2.85 |
| 16036 | 4 |
| 20045 | 3.5 |
| 24054 | 3.5 |
| 28063 | 4 |
| 32072 | 2.85 |
| 36081 | 2.5 |
| 40090 | 1 |

TABLE 22

| Freq | Amplitude |
|---|---|
| 0 | 2.5 |
| 4009 | 1 |
| 8018 | 2.5 |
| 12027 | 2.85 |
| 16036 | 4.5 |
| 20045 | 3.5 |
| 24054 | 3.5 |
| 28063 | 4.5 |
| 32072 | 2.85 |
| 36081 | 2.5 |
| 40090 | 1 |

TABLE 23

| Freq | Amplitude |
|---|---|
| 0 | 1.9 |
| 2321 | 1.8 |
| 4642 | 1 |
| 6963 | 1.2 |
| 9284 | 1.3 |
| 11605 | 1.4 |
| 13926 | 1.5 |
| 16247 | 1.6 |
| 18568 | 2.1 |
| 20889 | 2 |
| 23210 | 2 |
| 25531 | 2.1 |
| 27852 | 1.6 |
| 30173 | 1.5 |
| 32494 | 1.4 |
| 34815 | 1.3 |
| 37136 | 1.2 |
| 39457 | 1 |
| 41778 | 1.8 |

TABLE 24

| Freq | Amplitude |
|---|---|
| 0 | 2.5 |
| 4009 | 1.5 |
| 8018 | 2.5 |
| 12027 | 2.85 |
| 16036 | 4 |
| 20045 | 3.5 |
| 24054 | 3.5 |
| 28063 | 4 |
| 32072 | 2.85 |
| 36081 | 2.5 |
| 40090 | 1.5 |

TABLE 25

| Frequency | Amplitude |
|---|---|
| 0 | 3 |
| 4009 | 2 |
| 8018 | 2.5 |
| 12027 | 2.85 |
| 16036 | 4 |
| 20045 | 3.5 |
| 24054 | 3.5 |
| 28063 | 4 |
| 32072 | 2.85 |
| 36081 | 2.5 |
| 40090 | 2 |

TABLE 26

| Frequency | Amplitude |
|---|---|
| 0 | 3 |
| 4009 | 1.5 |
| 8018 | 2.5 |
| 12027 | 2.85 |
| 16036 | 4 |
| 20045 | 3.5 |
| 24054 | 3.5 |
| 28063 | 4 |
| 32072 | 2.85 |
| 36081 | 2.5 |
| 40090 | 1.5 |

TABLE 27

| Freq | Amplitude |
|---|---|
| 0 | 1.9 |
| 2321 | 1.8 |
| 4642 | 1 |
| 6963 | 1.5 |
| 9284 | 1.6 |
| 11605 | 1.7 |
| 13926 | 1.8 |
| 16247 | 1.9 |
| 18568 | 2.2 |
| 20889 | 2 |
| 23210 | 2 |
| 25531 | 2.2 |
| 27852 | 1.9 |
| 30173 | 1.8 |
| 32494 | 1.7 |
| 34815 | 1.6 |
| 37136 | 1.5 |
| 39457 | 1 |
| 41778 | 1.8 |

TABLE 28

| Freq | Amplitude | Time Coefficient | Phase |
|---|---|---|---|
| 0 | 2.5 | 2.8636 | 0 |
| 4009 | 1 | 0.6084 | 3.1416 |
| 8018 | 2.5 | 0.1736 | 3.1416 |
| 12027 | 3.5 | 0.2247 | 0 |
| 16036 | 4 | 0.1454 | 0 |
| 20045 | 3.5 | 0.23 | 0 |
| 24054 | 3.5 | 0.23 | 0 |
| 28063 | 4 | 0.1454 | 0 |
| 32072 | 3.5 | 0.2247 | 0 |
| 36081 | 2.5 | 0.1736 | 3.1416 |
| 40090 | 1 | 0.6084 | 3.1416 |

Phase means phase of the time coefficient.
All Frequency phases are zero.

TABLE 29

| Freq | Amplitude |
|---|---|
| 0 | 2 |
| 1131 | 1.66 |
| 2262 | 1.33 |
| 3393 | 1 |
| 4524 | 1 |
| 5655 | 1.3 |
| 6786 | 1.4 |
| 7917 | 1.5 |
| 9048 | 1.6 |
| 10179 | 1.7 |
| 11310 | 1.8 |
| 12441 | 1.9 |
| 13572 | 2 |
| 14703 | 2.1 |
| 15834 | 2.2 |
| 16965 | 2.4 |
| 18096 | 2.5 |
| 19227 | 2.6 |
| 20358 | 2.7 |
| 21489 | 2.8 |
| 22620 | 2.7 |
| 23751 | 2.6 |
| 24882 | 2.5 |
| 26013 | 2.4 |
| 27144 | 2.3 |
| 28275 | 2.2 |
| 29406 | 2.1 |
| 30537 | 2 |
| 31668 | 1.9 |
| 32799 | 1.8 |
| 33930 | 1.7 |
| 35061 | 1.6 |
| 36192 | 1.5 |
| 37323 | 1.4 |
| 38454 | 1.3 |
| 39585 | 1 |
| 40716 | 1 |
| 41847 | 1.33 |
| 42978 | 1.66 |

TABLE 30

| Frequency | Amplitude |
|---|---|
| 0 | 2.5 |
| 4009 | 2 |
| 8018 | 2.5 |
| 12027 | 2.85 |
| 16036 | 4.5 |
| 20045 | 3.5 |
| 24054 | 3.5 |
| 28063 | 4.5 |
| 32072 | 2.85 |
| 36081 | 2.5 |
| 40090 | 2 |

TABLE 31

| Frequency | Amplitude |
|---|---|
| 0 | 2.5 |
| 2321 | 2.5 |
| 4642 | 2.15 |
| 6963 | 2.4 |
| 9284 | 2.6 |
| 11605 | 2.9 |
| 13926 | 3.78 |
| 16247 | 4.6 |
| 18568 | 2.6 |
| 20889 | 4 |
| 23210 | 4 |
| 25531 | 2.6 |
| 27852 | 4.6 |
| 30173 | 3.78 |
| 32494 | 2.9 |
| 34815 | 2.6 |
| 37136 | 2.4 |
| 39457 | 2.15 |
| 41778 | 2.5 |

TABLE 32

| Freq | Amplitude |
|---|---|
| 0 | 1.6 |
| 2321 | 1.5 |
| 4642 | 1 |
| 6963 | 1.12 |
| 9284 | 1.2 |
| 11605 | 1.3 |
| 13926 | 1.4 |
| 16247 | 1.6 |
| 18568 | 2 |
| 20889 | 1.9 |
| 23210 | 1.9 |
| 25531 | 2 |
| 27852 | 1.6 |
| 30173 | 1.4 |
| 32494 | 1.3 |
| 34815 | 1.2 |
| 37136 | 1.12 |
| 39457 | 1 |
| 41778 | 1.5 |

TABLE 33

| Freq | Amplitude | Time Coefficients | Phase |
|---|---|---|---|
| 0 | 3 | 1.2759 | 0 |
| 1521 | 2 | 0.2615 | 0 |
| 3042 | 3 | 0.2209 | 0 |
| 4563 | 1 | 0.1608 | 0 |
| 6084 | 1 | 0.0913 | 0 |
| 7605 | 1 | 0.0239 | 0 |
| 9126 | 1 | 0.0308 | 3.1416 |
| 10647 | 1 | 0.0644 | 3.1416 |
| 12168 | 1 | 0.0729 | 3.1416 |
| 13689 | 1 | 0.0567 | 3.1416 |
| 15210 | 1 | 0.0208 | 3.1416 |
| 16731 | 1 | 0.0264 | 0 |
| 18252 | 1 | 0.0745 | 0 |
| 19773 | 1 | 0.1134 | 0 |
| 21294 | 1 | 0.1351 | 0 |
| 22815 | 1 | 0.1351 | 0 |
| 24336 | 1 | 0.1134 | 0 |
| 25857 | 1 | 0.0745 | 0 |
| 27378 | 1 | 0.0264 | 0 |
| 28899 | 1 | 0.0208 | 3.1416 |
| 30420 | 1 | 0.0567 | 3.1416 |
| 31941 | 1 | 0.0729 | 3.1416 |
| 33462 | 1 | 0.0644 | 3.1416 |
| 34983 | 1 | 0.0308 | 3.1416 |
| 36504 | 1 | 0.0239 | 0 |
| 38025 | 1 | 0.0913 | 0 |
| 39546 | 1 | 0.1608 | 0 |
| 41067 | 3 | 0.2209 | 0 |
| 42588 | 2 | 0.2615 | 0 |

Phase means phase of the time coefficient. All Frequency phases are zero.

TABLE 34

| Freq | Amplitude | Time Coefficient | Phase |
|---|---|---|---|
| 0 | 2 | 1.9487 | 0 |
| 1131 | 1 | 0.0506 | 3.1416 |
| 2262 | 2 | 0.0486 | 3.1416 |
| 3393 | 2 | 0.0454 | 3.1416 |
| 4524 | 2 | 0.041 | 3.1416 |
| 5655 | 2 | 0.0355 | 3.1416 |
| 6786 | 2 | 0.0291 | 3.1416 |
| 7917 | 2 | 0.022 | 3.1416 |
| 9048 | 2 | 0.0143 | 3.1416 |
| 10179 | 2 | 0.0062 | 3.1416 |
| 11310 | 2 | 0.0021 | 0 |
| 12441 | 2 | 0.0103 | 0 |
| 13572 | 2 | 0.0182 | 0 |
| 14703 | 2 | 0.0256 | 0 |
| 15834 | 2 | 0.0324 | 0 |
| 16965 | 2 | 0.0384 | 0 |
| 18096 | 2 | 0.0433 | 0 |
| 19227 | 2 | 0.0472 | 0 |
| 20358 | 2 | 0.0498 | 0 |
| 21489 | 2 | 0.0511 | 0 |
| 22620 | 2 | 0.0511 | 0 |
| 23751 | 2 | 0.0498 | 0 |
| 24882 | 2 | 0.0472 | 0 |
| 26013 | 2 | 0.0433 | 0 |
| 27144 | 2 | 0.0384 | 0 |
| 28275 | 2 | 0.0324 | 0 |
| 29406 | 2 | 0.0256 | 0 |
| 30537 | 2 | 0.0182 | 0 |
| 31668 | 2 | 0.0103 | 0 |
| 32799 | 2 | 0.0021 | 0 |
| 33930 | 2 | 0.0062 | 3.1416 |
| 35061 | 2 | 0.0143 | 3.1416 |
| 36192 | 2 | 0.022 | 3.1416 |
| 37323 | 2 | 0.0291 | 3.1416 |
| 38454 | 2 | 0.0355 | 3.1416 |
| 39585 | 2 | 0.041 | 3.1416 |
| 40716 | 2 | 0.0454 | 3.1416 |
| 41847 | 2 | 0.0486 | 3.1416 |
| 42978 | 1 | 0.0506 | 3.1416 |

Phase means phase of the time coefficient. All Frequency phases are zero.

1. A frequency response for enhancing the quality of an input audio signal made up of a plurality of signal components, each signal component having an amplitude and a frequency, and the frequencies of the input audio signal being within a band of frequencies having a low end and a high end, at least a portion of which being within the range of normal human hearing, said frequency response comprising a curve with a shape, wherein the input audio signal becomes an enhanced audio signal when distorted in accordance with the shape of said curve, the input audio signal is distorted in accordance with the shape of said curve when signal components having frequencies between a reference frequency and the high end increase in amplitude as per increasing frequencies from the reference frequency toward the high end, over at least a portion of the band of frequencies, and the enhanced audio signal is recognizable as being the input audio signal enhanced such that audible sound reproduced from the enhanced audio signal exhibits a perceptively improved harmonic quality and sound source separation compared to audible sound reproduced from the undistorted input audio signal.

2. The frequency response as set forth in claim 1, wherein the input audio signal is distorted in accordance with the shape of said curve when signal components having frequencies between the reference frequency and the high end increase in amplitude up to a significant amplitude peak and there is up to a total of only three significant amplitude peaks between the low end and the high end.

3. An apparatus for enhancing the quality of an input audio signal made up of a plurality of signal components, each signal component having an amplitude and a frequency, and the frequencies of the input audio signal being within a band of frequencies having a low end and a high end, at least a portion of which being within the range of normal human hearing, said apparatus being operatively adapted for distorting the input audio signal according to a frequency response curve such that, when the input audio signal is transmitted through said apparatus, said input audio signal is distorted into an enhanced audio signal such that signal components having frequencies between a reference frequency and the high end increase in amplitude as per increasing frequencies from the reference frequency toward the high end, over at least a portion of the band of frequencies,
wherein said frequency response curve does not vary according to the amplitude of the input audio signal, and the enhanced audio signal is recognizable as being the input audio signal enhanced such that audible sound reproduced from the enhanced audio signal exhibits a perceptively improved harmonic quality and sound source separation compared to audible sound reproduced from the input audio signal.

4. An apparatus for enhancing the quality of an input audio signal made up of a plurality of signal components, each signal component having an amplitude and a frequency, and the frequencies of the input audio signal being within a band of frequencies having a low end and a high end, at least a portion of which being in the range of normal human hearing, said apparatus being operatively adapted for distorting the input audio signal, when transmitted therethrough, into an enhanced audio signal such that signal components having frequencies between a reference frequency and the high end increase in amplitude as per increasing frequencies from the reference frequency toward the high end, over at least a portion of the band of frequencies,
wherein the enhanced audio signal is recognizable as being an enhanced version of the input audio signal, and said apparatus enhances the input audio signal such that audible sound reproduced from the enhanced audio signal exhibits a perceptively improved harmonic quality and sound source separation compared to audible sound reproduced from the undistorted input audio signal, with said apparatus creating an impulse response that unmasks typically masked tones of the input audio signal by stretching the tone in the time domain long enough to be heard but not so long as to be blurred.

5. The apparatus as set forth in claim 4, wherein said apparatus stretches the tone to at least about 0.1 milliseconds in duration.

6. The apparatus as set forth in claim 4, wherein said apparatus provides an amplitude shaping function that overcomes both the pitch-loudness phenomenon and the suppression phenomenon by possessing the impulse response characteristics of a relatively long lasting impulse response and an impulse response with a wide-band characteristic.

7. A method of enhancing the quality of an audio signal, comprising:
providing an input audio signal made up of a plurality of signal components, each signal component having an amplitude and a frequency, and the frequencies of the input audio signal being within a band of frequencies having a low end and a high end, at least a portion of which being within the range of normal human hearing; and
distorting the input audio signal into an enhanced audio signal such that signal components having frequencies between a reference frequency and the high end increase in amplitude as per increasing frequencies from the reference frequency toward the high end, over at least a portion of the band of frequencies, such that the enhanced audio signal is recognizable as being the input audio signal enhanced such that audible sound reproduced from the enhanced audio signal exhibits a perceptively improved harmonic quality and sound source separation compared to audible sound reproduced from the undistorted input audio signal;
wherein the enhanced audio signal is not normalized to a flat frequency response.

8. The method as set forth in claim 4, wherein said method further comprises processing the enhanced audio signal into sound and the enhanced audio signal is not normalized to a flat frequency response before being processed into sound.

9. The method as set forth in claim 4, wherein said step of distorting includes further distorting the input audio signal such that the signal components having frequencies between the reference frequency and the high end increase in amplitude up to a significant amplitude peak and there is up to a total of only three significant amplitude peaks between the low end and the high end.

10. A method of enhancing the quality of an audio signal, comprising:
providing an input audio signal made up of a plurality of signal components, each signal component having an amplitude and a frequency, and the frequencies of the input audio signal being within a band of frequencies having a low end and a high end, at least a portion of which being within the range of normal human hearing;
distorting the input audio signal into an enhanced audio signal such that signal components having frequencies between a reference frequency and the high end increase in amplitude as per increasing frequencies from the reference frequency toward the high end, over at least a portion of the band of frequencies, such that the enhanced audio signal is recognizable as being the input audio signal enhanced such that audible sound reproduced from the enhanced audio signal exhibits a perceptively improved harmonic quality and sound source separation compared to audible sound reproduced from the undistorted input audio signal; and
compressing the enhanced audio signal.

11. The method as set forth in claim 10, wherein the input audio signal is a digital audio signal, and the enhanced audio signal is compressed before being transmitted to a location.

12. The method as set forth in claim 10, wherein the input audio signal is a digital audio signal, and the enhanced audio signal is compressed before being converted into sound.

13. A method of enhancing the quality of an audio signal, comprising:
providing an input audio signal made up of a plurality of signal components, each signal component having an amplitude and a frequency, and the frequencies of the input audio signal being within a band of frequencies having a low end and a high end, at least a portion of which being within the range of normal human hearing;
distorting the input audio signal into an enhanced audio signal, according to a frequency response curve having a width, such that signal components having frequencies between a reference frequency and the high end increase in amplitude as per increasing frequencies from the reference frequency toward the high end, over at least a portion of the band of frequencies, such that the enhanced audio signal is recognizable as being the input audio signal enhanced such that audible sound reproduced from the enhanced audio signal exhibits a perceptively improved harmonic quality and sound source separation compared to audible sound reproduced from the undistorted input audio signal;
processing the input audio signal through an audio system having a bandwidth; and
reducing the width of the frequency response curve so as to fit at least mostly within the bandwidth of the audio system.

14. The method as set forth in claim 13, wherein the input audio signal is processed through the audio system before being distorted into an enhanced audio signal.

15. The method as set forth in claim 13, wherein the input audio signal is distorted into an enhanced audio signal before being processed through the audio system.

16. The method as set forth in claim 13, wherein said step of distorting includes further distorting the input audio signal such that the signal components having frequencies between the reference frequency and the high end increase in amplitude up to a significant amplitude peak and there is up to a total of only three significant amplitude peaks between the low end and the high end.

17. The method as set forth in claim 16, wherein the reduction of the width of the frequency response curve so as to fit at least mostly within the bandwidth of the audio system is accomplished by reducing the reference frequency and the frequencies of the significant amplitude peaks proportionally the same.

18. The method as set forth in claim 16, wherein the reduction of the width of the frequency response curve so as to fit at least mostly within the bandwidth of the audio system is accomplished by reducing one or more of the reference frequency and the frequencies of the significant amplitude peaks disproportionately.
